(19) United States
(12) Patent Application Publication
(10) Pub. No.: US 2009/0159968 A1
(43) Pub. Date: Jun. 25, 2009

(54) BVDII Enhancement with a Cascode DMOS

(75) Inventors: Steve L. Merchant, Manchester, NH (US); John Lin, Chelmsford, MA (US); Sameer Pendharkar, Allen, TX (US); Philip L. Hower, Concord, MA (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/960,432

(22) Filed: Dec. 19, 2007

(51) Int. Cl. H01L 27/088; H01L 21/8234

(52) U.S. Cl. 257/337; 438/276; 257/E27.06; 257/E21.616

(57) ABSTRACT

Double diffused MOS (DMOS) transistors feature extended drain regions to provide depletion regions which drop high drain voltages to lower voltages at the gate edges. DMOS transistors exhibit lower drain breakdown potential in the on-state than in the off-state than in the off-state due to snapback by a parasitic bipolar transistor that exists in parallel with the DMOS transistor. The instant invention is a cascoded DMOS transistor in an integrated circuit incorporating an NMOS transistor on the DMOS source node to reverse bias the parasitic emitter-base junction during on-state operation, eliminating snapback. The NMOS transistor may be integrated with the DMOS transistor by connections in the interconnect system of the integrated circuit, or the NMOS transistor and DMOS transistor may be fabricated in a common p-type well and integrated in the IC substrate. Methods of fabricating an integrated circuit with the incentive cascoded DMOS transistor are also disclosed.

### FIELD OF THE INVENTION

This invention relates to the field of integrated circuits. More particularly, this invention relates to improved high voltage MOS transistors.

### BACKGROUND OF THE INVENTION

Power integrated circuits frequently are designed to work with voltages over 50 volts. A common component for handling this voltage range is the double diffused MOS (DMOS) transistor, which features an extended drain to provide a depletion region which drops a high drain voltage (over 50 volts) to a lower voltage at the gate edge. DMOS transistors exhibit lower drain breakdown potential in the on-state, in which the gate of the DMOS transistor is biased to form an inversion channel under the gate in the substrate of the DMOS transistor, than in the off-state, in which the gate is biased to accumulate the substrate under the gate. The lower breakdown potential in on-state operation is due to snapback by a parasitic bipolar transistor that exists in parallel with the DMOS transistor. The lower breakdown potential in on-state operation limits the maximum voltage that can be applied to the DMOS in operation of the integrated circuit, known as the safe operating area (SOA). Commonly used methods to reduce snapback in the parasitic bipolar transistor have disadvantages. For example, DMOS transistors fabricated with additional ion implantation processes add cost and complexity to the integrated circuit.

### SUMMARY OF THE INVENTION

This Summary is provided to comply with 37 C.F.R. §1.73, requiring a summary of the invention briefly indicating the nature and substance of the invention. It is submitted with the understanding that it will not be used to interpret or limit the scope or meaning of the claims.

The instant invention is a cascoded DMOS transistor in an integrated circuit incorporating an NMOS transistor on the DMOS source node. The gates of the DMOS transistor and NMOS transistor are connected to form a common gate node of the inventive cascoded DMOS transistor. The body of the DMOS transistor is connected to the source of the NMOS transistor. The NMOS transistor may be fabricated in a separate p-type well from the DMOS transistor and integrated with the DMOS transistor by connections in the interconnect system of the integrated circuit, or the NMOS transistor and DMOS transistor may be fabricated in a common p-type well and integrated by sharing a common n-type region for the DMOS source and NMOS drain. Methods of fabricating an integrated circuit with the inventive cascoded DMOS transistor are also disclosed.

### DESCRIPTION OF THE VIEWS OF THE DRAWING

FIG. 1 is a schematic diagram of the instant invention.

FIG. 2A through FIG. 2I are cross-sections of an integrated circuit at various stages of fabrication with a DMOS cascaded with an NMOS transistor configured in a first embodiment of the instant invention.

FIG. 3A through FIG. 3H are cross-sections of an integrated circuit at various stages of fabrication with a DMOS cascaded with an NMOS transistor configured in an alternate embodiment.

### DETAILED DESCRIPTION

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

In this disclosure, the term DMOS will be understood to refer to an n-channel MOS transistor with an extended drain region. The term NMOS will be understood to refer to a conventional n-channel MOS transistor. The term IC will be understood to refer to an integrated circuit. A diffused contact region will be understood to refer to a region at a top surface of a substrate of an integrated circuit which is heavily doped to reduce an electrical resistance of a contact to the diffused contact region.

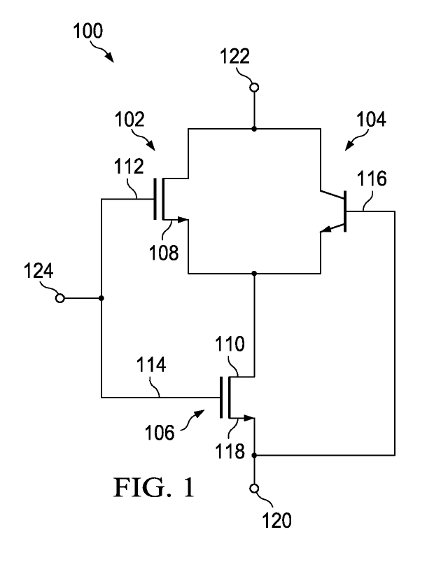

The problem of reduced breakdown in a DMOS transistor at high current in an on-state is solved by the instant invention, which is a DMOS transistor cascoded with an NMOS transistor. A schematic diagram of the instant invention is shown in FIG. 1. The inventive cascoded DMOS (100) includes a DMOS transistor (102) with a parasitic bipolar transistor (104), and an NMOS transistor (106). As detailed above, a DMOS source node (108) of the DMOS transistor (102) is connected to a drain node (110) of the NMOS transistor (106). A DMOS gate node (112) is connected to an NMOS gate node (114). A base node (116) of the parasitic bipolar transistor, which coincides with a body node of the DMOS transistor (102) is connected to an NMOS source node (118), which is in turn connected to a cascoded DMOS source node (120). The cascoded DMOS (100) is thus a three terminal device, with a drain node (122) coincident with the DMOS drain, a gate node (124) connected to the DMOS gate node (112) and the NMOS gate node (114), and the cascoded DMOS source node (120).

During operation of the cascoded DMOS of the instant invention, current through the DMOS transistor (102) also passes through the NMOS transistor (106), which causes a voltage on the NMOS drain node (110). The voltage on the drain node reverse biases an emitter base junction of the parasitic bipolar transistor (104), thus eliminating snapback of the parasitic bipolar transistor (104). As a result, higher voltages may be applied to the cascoded DMOS drain node (122) in an on-state than would be possible in a DMOS transistor without the NMOS transistor cascoded on the DMOS source node.

A channel length and a channel width of the NMOS transistor (106) may be sized to provide levels of impedance at low and high on-state drive currents to attain a desired safe operating area. It has been found that a channel width of the NMOS transistor (106) that is between one-third and two-thirds a channel width of the DMOS transistor (102) provides greater than 30 percent higher operating voltage in the safe operating area.

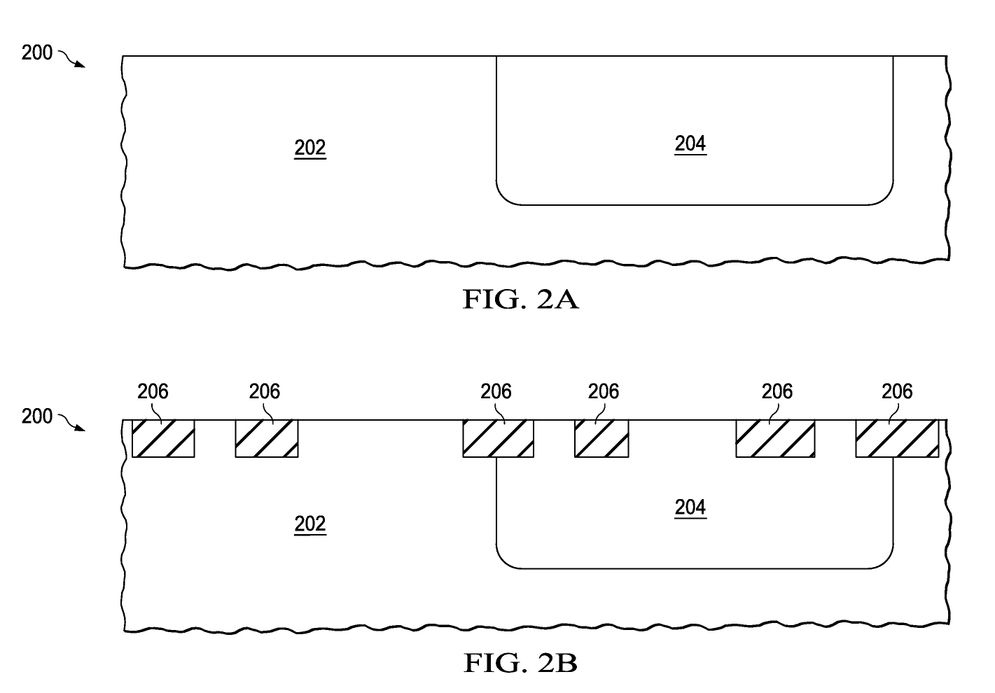

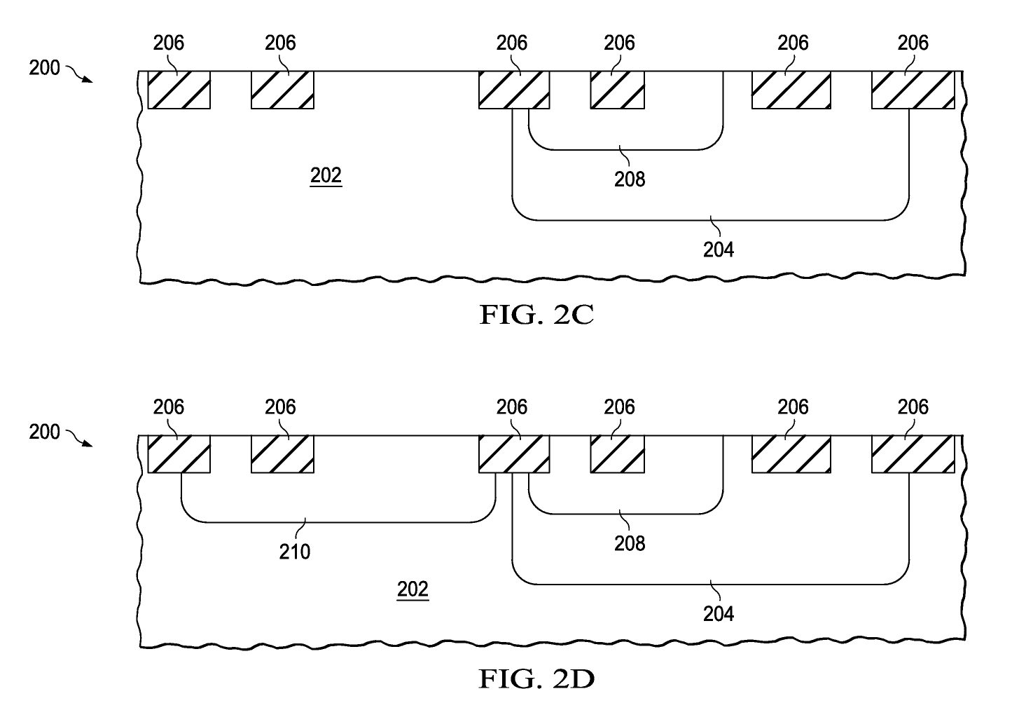

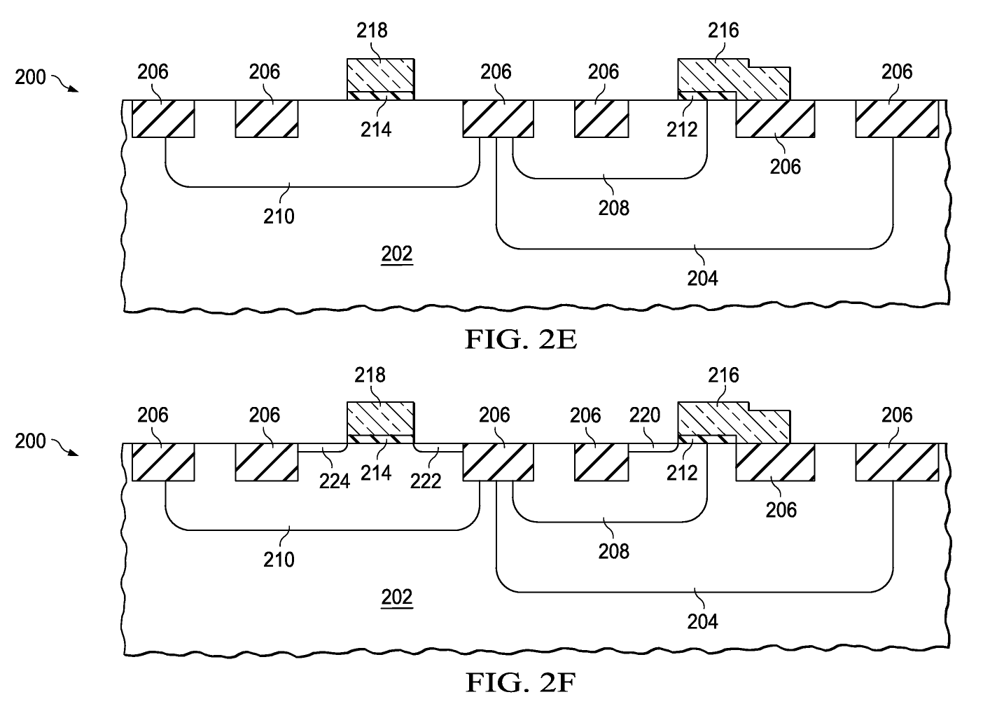

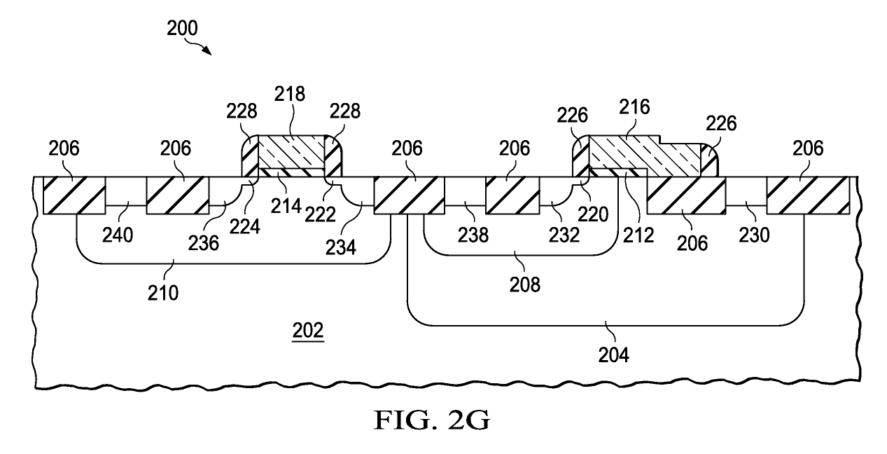

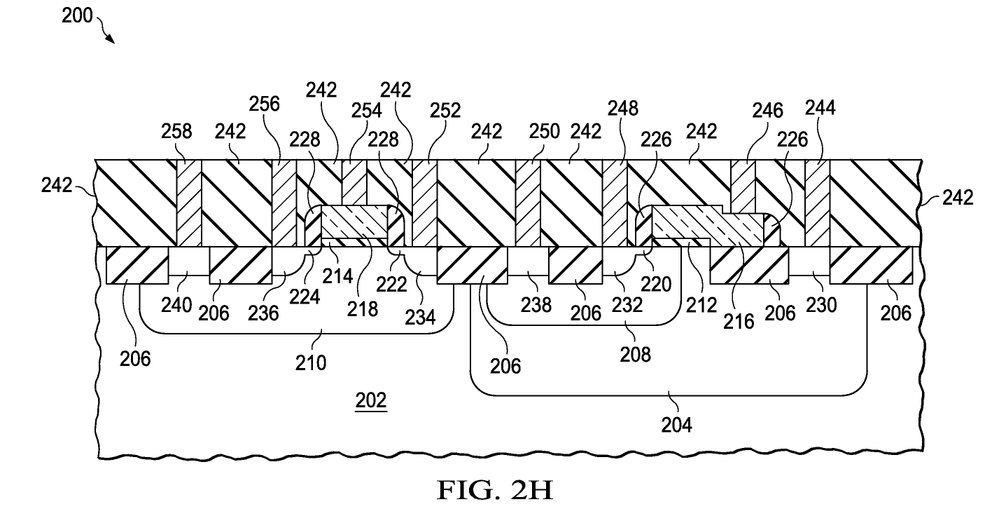

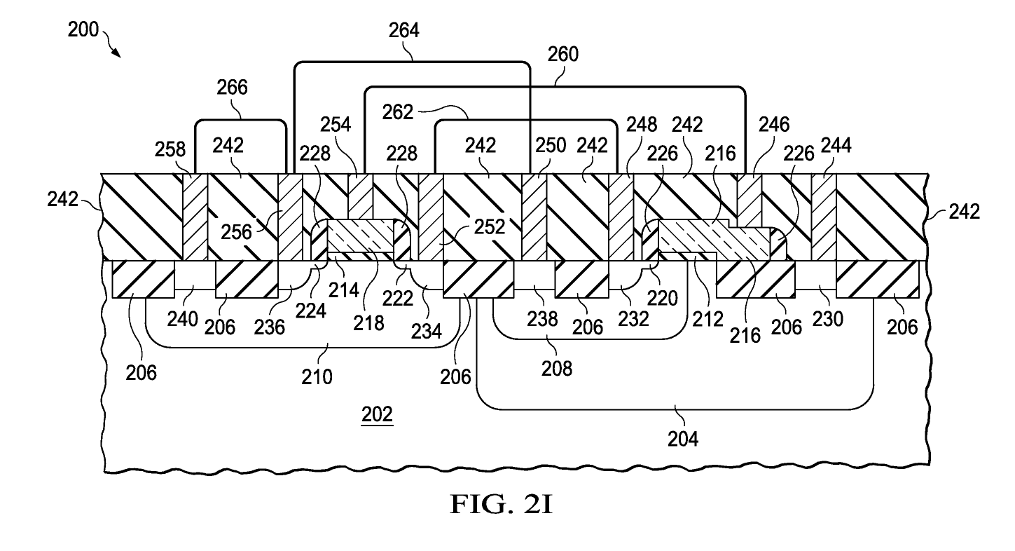

FIG. 2A through FIG. 2I are cross-sections of an integrated circuit at various stages of fabrication with a DMOS cascaded with an NMOS transistor configured in a first embodiment of the instant invention. FIG. 2A depicts an IC (200) which includes a p-type substrate (202), typically formed of epitaxial silicon with an electrical resistivity from 1 to 100 ohm-cm. An n-type well, hereafter referred to as a Deep Nwell (204), is formed in the substrate (202) by known processes of forming a first photoresist pattern to define the region for the Deep Nwell by photolithographic processes, ion implanting n-type dopants, typically phosphorus and arsenic in a dose range from 1·10¹¹ to 1·10¹⁴ cm⁻², at energies for the phosphorus from 0.5 to 3.0 MeV and energies for the arsenic below 1.0 MeV, followed by annealing, typically above 1100 C for more than 60 minutes. The resulting Deep Nwell (204) extends from a top surface of the substrate (202) to more than 2 microns into the substrate (202).

Referring to FIG. 2B, fabrication of the IC (200) continues with formation of regions of field oxide (206) at the top surface of the substrate (202). Field oxide (206) is typically 0.3 to 0.6 microns thick silicon dioxide formed by shallow trench isolation (STI) or local oxidation of silicon (LOCOS).

Referring to FIG. 2C, fabrication of the IC (200) continues with formation of a first p-type well (208); in the instant embodiment, the first p-type well (208) is formed within the Deep Nwell (204). The first p-type well (208) is formed by known processes including forming a second photoresist pattern to define regions for the first p-type well, ion implanting p-type dopants such as boron in a dose range of 1·10¹³ to 1·10¹⁶ cm⁻², at energies from 30 keV to 300 keV, followed by an anneal to repair damage to the substrate (202) from the ion implantation process. Electrical properties of the first p-type well (208) are optimized for operation of a DMOS transistor.

Referring to FIG. 2D, fabrication of the IC (200) continues with formation of a second p-type well (210); in the instant embodiment, the second p-type well (210) is formed within the substrate (202) outside the Deep Nwell (204). The second p-type well (210) is typically formed by known processes including forming a third photoresist pattern to define regions for the second p-type well, ion implanting p-type dopants such as boron in several steps in dose ranges of 1·10¹³ to 1·10¹⁶ cm⁻², at energies from 10 keV to 500 keV, followed by an anneal to repair damage to the substrate (202) from the ion implantation processes. Electrical properties of the second p-type well (210) are optimized for operation of a NMOS transistor.

Referring to FIG. 2E, fabrication of the IC (200) continues with formation of a first gate dielectric layer (212) on a portion of a top surface of the first p-type well (208) and a portion of a top surface of the Deep Nwell (204), typically of silicon dioxide, silicon oxy-nitride, hafnium oxide, layers of silicon dioxide and silicon nitride, or other insulating material, which is optimized for operation of a DMOS transistor. A second gate dielectric layer (214) typically of silicon dioxide, silicon oxy-nitride, hafnium oxide, layers of silicon dioxide and silicon nitride, or other insulating material, optimized for an NMOS transistor is formed on a portion of a top surface of the second p-type well (210). A DMOS gate (216) is formed on a top surface of the first gate dielectric layer (212), and an NMOS gate (218) is formed on a top surface of the second gate dielectric layer (214).

Referring to FIG. 2F, fabrication of the IC (200) continues with formation of lightly doped source and drain (LDD) regions for the DMOS and NMOS transistors. A DMOS source LDD (220) is formed in the source region of the DMOS transistor, typically by ion implantation of n-type dopants such as phosphorus and/or arsenic. It is within the scope of the instant invention to perform the ion implantation of the DMOS LDD earlier in the process sequence. An NMOS drain LDD (222) and NMOD source LDD (224) are formed in the source and drain regions, respectively, of the NMOS transistor, typically by ion implantation of n-type dopants such as phosphorus and/or arsenic, in a dose range from 1·10¹² to 1·10¹⁵ cm⁻², at energies from 2 keV to 30 keV.

Referring to FIG. 2G, fabrication of the IC (200) continues with formation of DMOS gate sidewall spacers (226) and NMOS gate sidewall spacers (228), commonly formed by deposition of spacer material, typically of silicon nitride, followed by anisotropic etchback to remove the spacer material from horizontal surfaces and leave spacer material on lateral surfaces of the DMOS gate (216) and NMOS gate (218). A DMOS drain diffused contact region (230) and DMOS source diffused contact region (232) are formed by ion implantation of n-type dopants, such as phosphorus and/or arsenic, in dose ranges from 1·10¹⁴ to 1·10¹⁶ cm⁻², at energies from 5 keV to 100 keV. An NMOS drain diffused contact region (234) and NMOS source diffused contact region (236) are also formed by ion implantation of n-type dopants, such as phosphorus and/or arsenic, in dose ranges from 1·10¹⁴ to 1·10¹⁶ cm⁻², at energies from 5 keV to 100 keV. It is within the scope of the instant invention to form the DMOS drain and source diffused contact regions (230, 132) in a same set or a different set of ion implantation operations as the NMOS drain and source diffused contact regions (234, 136). A DMOS body diffused contact region (238) is formed by ion implanting p-type dopants, such as boron and/or gallium, in dose ranges from 1·10¹⁴ to 1·10¹⁶ cm⁻², at energies from 5 keV to 100 keV. Similarly, an NMOS body diffused contact region (240) is formed by ion implanting p-type dopants, such as boron and/or gallium, in dose ranges from 1·10¹⁴ to 1·10¹⁶ cm⁻², at energies from 5 keV to 100 keV. It is within the scope of the instant invention to form the DMOS body diffused contact region (238) in a same set or a different set of ion implantation operations as the NMOS body diffused contact region (240).

A DMOS transistor is formed by the DMOS drain diffused contact region (230) and Deep Nwell (204), which form a drain of the DMOS transistor, the first p-type well (208), which forms a body of the DMOS transistor, the DMOS source diffused contact region (232), which forms a source of the DMOS transistor, the DMOS gate dielectric layer (212), which forms a gate insulator of the DMOS transistor, and the DMOS gate (216), which forms a gate of the DMOS transistor. It is within the scope of the instant invention to have variations of the drain structure of the DMOS transistor, including a configuration in which the DMOS drain diffused contact region (230) is separated from the DMOS gate (216) by a silicide block layer, which is a patterned layer of dielectric material, typically silicon nitride, which prevents metal silicide from forming on a region of active area, instead of field oxide. An NMOS transistor is formed by the NMOS drain diffused contact region (234), which forms a drain of the NMOS transistor, the second p-type well (210), which forms a body of the NMOS transistor, the NMOS source diffused contact region (236), which forms a source of the NMOS transistor, the NMOS gate dielectric layer (214), which forms a gate insulator of the NMOS transistor, and the NMOS gate (218), which forms a gate of the NMOS transistor.

Referring to FIG. 2H, fabrication of the IC (200) continues with formation of a pre-metal dielectric layer (PMD) (242), typically of silicon dioxide, on a top surface of the IC (200). Contact holes are formed in the PMD (242) and filled with metal, typically tungsten, to form a DMOS drain contact (244) connected to the DMOS drain diffused contact region (230), a DMOS gate contact (246) connected to the DMOS gate (216), a DMOS source contact (248) connected to the DMOS source diffused contact region (232), a DMOS body contact (250) connected to the DMOS body diffused contact region (238), an NMOS drain contact (252) connected to the NMOS drain diffused contact region (234), an NMOS gate contact (254) connected to the NMOS gate (218), an NMOS source contact (256) connected to the NMOS source diffused contact region (236), and an NMOS body contact (258) connected to the NMOS body diffused contact region (240).

In the instant embodiment, elements of the DMOS transistor and elements of the NMOS transistor are electrically connected as described below, by forming metal interconnects, typically using horizontal metal lines and vertical metal vias, using known processes. The connections are shown schematically in FIG. 2I for clarity. Referring to FIG. 2I, the DMOS gate contact (246) is connected to the NMOS gate contact (254) by connection (260). The DMOS source contact (248) is connected to the NMOS drain contact (252) by connection (262). The DMOS body contact (250) is connected to the NMOS source contact (256) by connection (264). The NMOS source contact (256) is connected to the NMOS body contact by connection (266).

The embodiment depicted in FIG. 2A through FIG. 2I is advantageous because the use of separate p-type wells for the body of the DMOS transistor and the body of the NMOS transistor allows optimization of the electrical performance parameters, such as on-state drive current, of both transistors, and hence maximization of the safe operating area (SOA).

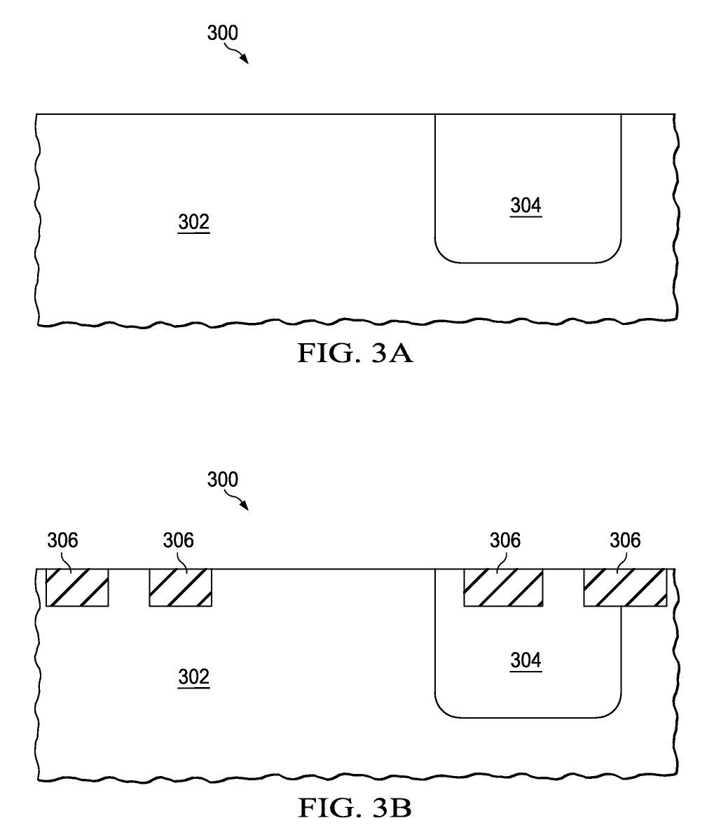

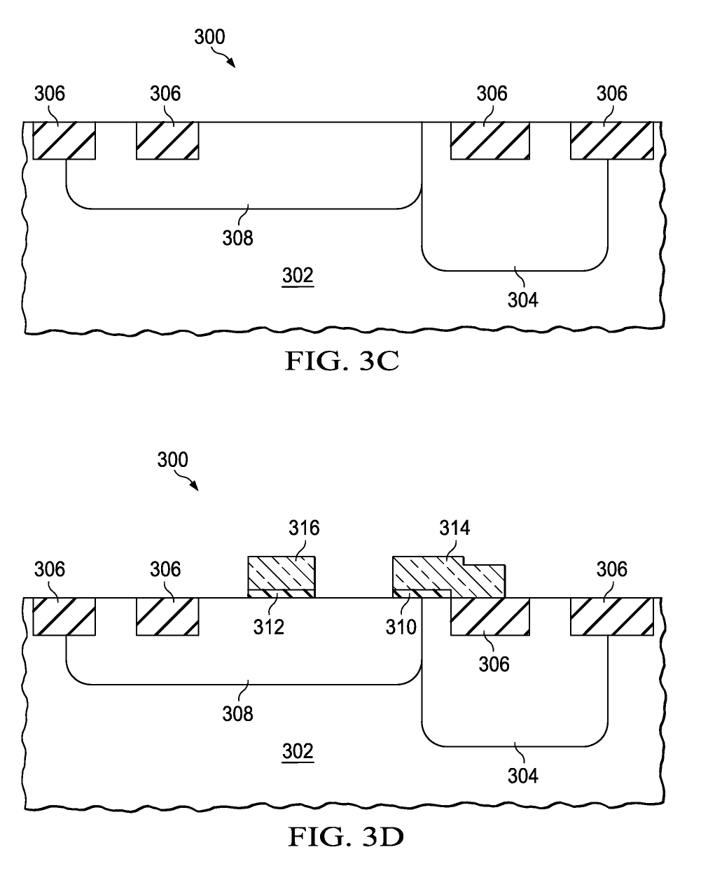

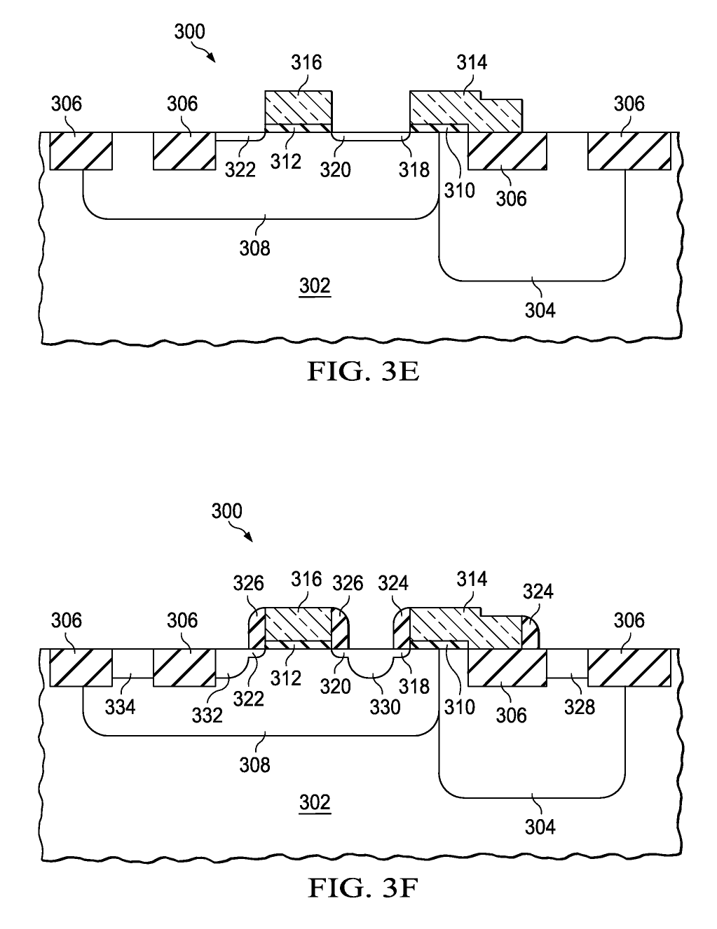

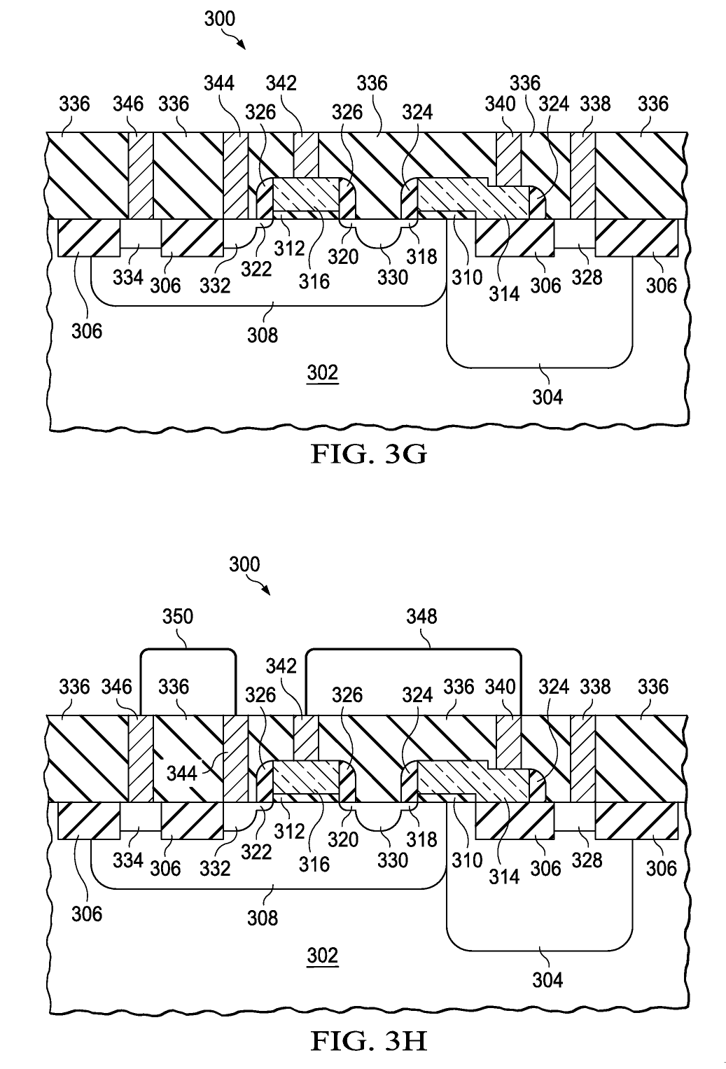

An alternate embodiment of the instant invention is depicted in FIG. 3A through FIG. 3H, which are cross-sections of an integrated circuit at various stages of fabrication with a DMOS cascaded with an NMOS transistor configured in the alternate embodiment. FIG. 3A depicts an IC (300) which includes a p-type substrate (302), typically formed of epitaxial silicon with an electrical resistivity from 1 to 100 ohm-cm. An n-type well, hereafter referred to as a Deep Nwell (304), is formed in the substrate (302) by known processes of forming a first photoresist pattern to define the region for the Deep Nwell by photolithographic processes, ion implanting n-type dopants, typically phosphorus and arsenic in a dose range from 1·10¹¹ to 1·10¹⁴ cm⁻², at energies for the phosphorus from 0.5 to 3.0 MeV and energies for the arsenic below 1.0 MeV, followed by annealing, typically above 1100 C for more than 60 minutes. The resulting Deep Nwell (304) extends from a top surface of the substrate (302) to more than 2 microns into the substrate (302).

Referring to FIG. 3B, fabrication of the IC (300) continues with formation of regions of field oxide (306) at the top surface of the substrate (302). Field oxide (306) is typically 0.3 to 0.6 microns thick silicon dioxide formed by shallow trench isolation (STI) or local oxidation of silicon (LOCOS).

Referring to FIG. 3C, fabrication of the IC (300) continues with formation of a p-type well (308); in the instant embodiment, the p-type well (308) is formed within the substrate (302) outside the Deep Nwell (304). The p-type well (308) is formed by known processes including forming a second photoresist pattern to define regions for the p-type well, ion implanting p-type dopants such as boron in a dose range of 1·10¹³ to 1·10¹⁶ cm⁻², at energies from 30 keV to 300 keV, followed by an anneal to repair damage to the substrate (302) from the ion implantation process. Electrical properties of the p-type well (308) are optimized for operation of a DMOS transistor. The p-type well (308) will provide the body node of the DMOS transistor and the body node of the NMOS transistor.

Referring to FIG. 3D, fabrication of the IC (300) continues with formation of a first gate dielectric layer (310) on a first portion of a top surface of the p-type well (308) and on a portion of a top surface of the Deep Nwell (304), typically of silicon dioxide, silicon oxy-nitride, hafnium oxide, layers of silicon dioxide and silicon nitride, or other insulating material, which is optimized for operation of a DMOS transistor. A second gate dielectric layer (312) typically of silicon dioxide, silicon oxy-nitride, hafnium oxide, layers of silicon dioxide and silicon nitride, or other insulating material, optimized for an NMOS transistor is formed on a second portion of the top surface of the p-type well (308). A DMOS gate (314) is formed on a top surface of the first gate dielectric layer (310), and an NMOS gate (316) is formed on a top surface of the second gate dielectric layer (312).

Referring to FIG. 3E, fabrication of the IC (300) continues with formation of lightly doped source and drain (LDD) regions for the DMOS and NMOS transistors. A DMOS source LDD (318) is formed in the source region of the DMOS transistor, typically by ion implantation of n-type dopants such as phosphorus and/or arsenic. It is within the scope of the instant invention to perform the ion implantation of the DMOS LDD earlier in the process sequence. An NMOS drain LDD (320) and NMOS source LDD (322) are formed in the source and drain regions, respectively, of the NMOS transistor, typically by ion implantation of n-type dopants such as phosphorus and/or arsenic, in a dose range from 1·10¹² to 1·10¹⁵ cm⁻², at energies from 2 keV to 30 keV.

Referring to FIG. 3F, fabrication of the IC (300) continues with formation of DMOS gate sidewall spacers (324) and NMOS gate sidewall spacers (326), commonly formed by deposition of spacer material, typically of silicon nitride, followed by anisotropic etchback to remove the spacer material from horizontal surfaces and leave spacer material on lateral surfaces of the DMOS gate (314) and NMOS gate (316). A DMOS drain diffused contact region (328), an integrated DMOS source and NMOS drain diffused contact region (330) and an NMOS source diffused contact region (332) are formed by ion implantation of n-type dopants, such as phosphorus and/or arsenic, in dose ranges from 1·10¹⁴ to 1·10¹⁶ cm⁻², at energies from 5 keV to 100 keV. An integrated DMOS body and NMOS body diffused contact region (334) is formed by ion implanting p-type dopants, such as boron and/or gallium, in dose ranges from 1·10¹⁴ to 1·10¹⁶ cm⁻², at energies from 5 keV to 100 keV.

A DMOS transistor is formed by the DMOS drain diffused contact region (328), Deep Nwell (304), p-type well (308), integrated DMOS source and NMOS drain diffused contact region (330), DMOS gate dielectric layer (310) and DMOS gate (314). It is within the scope of the instant invention to have variations of the drain structure of the DMOS transistor, including a configuration in which the DMOS drain diffused contact region (328) is separated from the DMOS gate (314) by a silicide block layer instead of field oxide. An NMOS transistor is formed by the integrated DMOS source and NMOS drain diffused contact region (330), the p-type well (308), the NMOS source diffused contact region (332), the NMOS gate dielectric layer (312) and the NMOS gate (316).

Referring to FIG. 3G, fabrication of the IC (300) continues with formation of a pre-metal dielectric layer (PMD) (336), typically of silicon dioxide, on a top surface of the IC (300). Contact holes are formed in the PMD (336) and filled with metal, typically tungsten, to form a DMOS drain contact (338) connected to the DMOS drain diffused contact region (328), a DMOS gate contact (340) connected to the DMOS gate (314), an NMOS gate contact (342) connected to the NMOS gate (312), an NMOS source contact (344) connected to the NMOS source diffused contact region (332), and an integrated DMOS body and NMOS body contact (346) connected to the integrated DMOS body and NMOS body diffused contact region (334).

In the instant embodiment, elements of the DMOS transistor and elements of the NMOS transistor are electrically connected as described below, by forming metal interconnects, typically using horizontal metal lines and vertical metal vias, using known processes. The connections are shown schematically in FIG. 3H for clarity. Referring to FIG. 3H, the DMOS gate contact (340) is connected to the NMOS gate contact (342) by connection (348). The NMOS source contact (344) is connected to the integrated DMOS body and NMOS body contact (346) by connection (350).

The embodiment depicted in FIG. 3A through FIG. 3H is advantageous because the use of a single p-type well for the body of the DMOS transistor and the body of the NMOS transistor, and the integration of the DMOS source with the NMOS drain allows optimization of the space in the integrated circuit needed to accommodate the instant invention.

What is claimed is:

1. A cascoded DMOS transistor, comprising:
a semiconductor substrate;
a DMOS transistor formed in said semiconductor substrate, further comprising:
a DMOS body formed in said semiconductor substrate;
a DMOS gate dielectric layer formed on a top surface of said DMOS body;
a DMOS gate formed on a top surface of said DMOS gate dielectric layer;
a DMOS drain formed in said semiconductor substrate adjacent to said DMOS gate; and
a DMOS source formed in said semiconductor substrate adjacent to said DMOS gate opposite from said DMOS drain;
an NMOS transistor formed in said semiconductor substrate, further comprising:
an NMOS body formed in said semiconductor substrate;
an NMOS gate dielectric layer formed on a top surface of said DMOS body;
an NMOS gate formed on a top surface of said DMOS gate dielectric layer;
an NMOS drain formed in said semiconductor substrate adjacent to said NMOS gate; and
an NMOS source formed in said semiconductor substrate adjacent to said NMOS gate opposite from said NMOS drain;
an electrical connection between said DMOS gate and said NMOS gate;
an electrical connection between said DMOS source and said NMOS drain;
an electrical connection between said DMOS body and said NMOS source; and
an electrical connection between said NMOS source and said NMOS body.

2. The cascoded DMOS transistor of claim 1, further comprising:
a first p-type well in said semiconductor substrate, whereby said DMOS body is formed in the first p-type well; and
a second p-type well in said semiconductor substrate, in a different region of said semiconductor substrate from said first p-type well, whereby said NMOS body is formed in the second p-type well.

3. The cascoded DMOS transistor of claim 2, in which a channel width of said NMOS transistor is between one-third and two-thirds a channel width of said DMOS transistor.

4. The cascoded DMOS transistor of claim 3, further comprising a DMOS drain diffused contact region formed in said DMOS drain, which is separated from said DMOS dielectric layer by a region of field oxide.

5. The cascoded DMOS transistor of claim 3, further comprising a DMOS drain diffused contact region formed in said DMOS drain, which is separated from said DMOS dielectric layer by a region of insulating material formed on a top surface of said semiconductor substrate.

6. The cascoded DMOS transistor of claim 1, further comprising a p-type well in said semiconductor substrate, whereby:
said DMOS body is formed in the p-type well; and
said NMOS body is formed in the p-type well.

7. The cascoded DMOS transistor of claim 6, in which said DMOS source and said NMOS drain are contiguous and formed by a same set of process operations.

8. The cascoded DMOS transistor of claim 7, in which a channel width of said NMOS transistor is between one-third and two-thirds a channel width of said DMOS transistor.

9. The cascaded DMOS transistor of claim 8, further comprising a DMOS drain diffused contact region formed in said DMOS drain, which is separated from said DMOS dielectric layer by a region of field oxide.

10. The cascaded DMOS transistor of claim 8, further comprising a DMOS drain diffused contact region formed in said DMOS drain, which is separated from said DMOS dielectric layer by a region of insulating material formed on a top surface of said semiconductor substrate.

11. A method of forming an integrated circuit, comprising the steps of:
providing a semiconductor substrate;
forming an n-type well in said semiconductor substrate;
forming regions of field oxide in said semiconductor substrate at a top surface of said semiconductor substrate;
forming a first p-type well in said n-type well;
forming a second p-type well in said semiconductor substrate in a region different from said n-type well;
forming a DMOS transistor, by a process further comprising the steps of:
forming a DMOS gate dielectric layer on said top surface of said semiconductor substrate in a region overlapping a portion of said first p-type well and a portion of said n-type well;
forming a DMOS gate on a top surface of said DMOS gate dielectric layer;
forming a DMOS drain diffused contact region in said n-type well;
forming a DMOS source diffused contact region in said first p-type well adjacent to said DMOS gate; and
forming a DMOS body diffused contact region in said first p-type well;
forming an NMOS transistor, by a process further comprising the steps of:
forming an NMOS gate dielectric layer on said top surface of said semiconductor substrate in a region over a portion of said second p-type well;
forming an NMOS gate on a top surface of said NMOS gate dielectric layer;
forming an NMOS drain diffused contact region in said second p-type well adjacent to said NMOS gate;
forming an NMOS source diffused contact region in said second p-type well adjacent to said NMOS gate; and
forming an NMOS body diffused contact region in said second p-type well;
forming an electrical connection between said DMOS gate and said NMOS gate;
forming an electrical connection between said DMOS source diffused contact region and said NMOS drain diffused contact region;
forming an electrical connection between said DMOS body diffused contact region and said NMOS source diffused contact region; and
forming an electrical connection between said NMOS source diffused contact region and said NMOS body diffused contact region.

12. The method of claim 11, in which a channel width of said NMOS transistor is between one-third and two-thirds a channel width of said DMOS transistor.

13. The method of claim 12, in which said DMOS drain diffused contact region is separated from said DMOS gate dielectric layer by a region of field oxide.

14. The method of claim 12, in which said DMOS drain diffused contact region is separated from said DMOS gate dielectric layer by a region of insulating material formed on a top surface of said semiconductor substrate.

15. A method of forming an integrated circuit, comprising the steps of:
providing a semiconductor substrate;
forming an n-type well in said semiconductor substrate;
forming regions of field oxide in said semiconductor substrate at a top surface of said semiconductor substrate;
forming a p-type well in said semiconductor substrate adjacent to and touching said n-type well;
forming a DMOS transistor, by a process further comprising the steps of:
forming a DMOS gate dielectric layer on said top surface of said semiconductor substrate in a region overlapping a portion of said p-type well and a portion of said n-type well;
forming a DMOS gate on a top surface of said DMOS gate dielectric layer;
forming a DMOS drain diffused contact region in said n-type well;
forming an integrated DMOS source and NMOS drain diffused contact region in said p-type well adjacent to said DMOS gate; and
forming an integrated DMOS body and NMOS body diffused contact region in said p-type well;
forming an NMOS transistor in which an NMOS drain is said integrated DMOS source and NMOS drain diffused contact region and an NMOS body contact region is said integrated DMOS body and NMOS body diffused contact region, by a process further comprising the steps of:
forming an NMOS gate dielectric layer on said top surface of said semiconductor substrate in a region over a portion of said p-type well adjacent to said integrated DMOS source and NMOS drain diffused contact region;
forming an NMOS gate on a top surface of said NMOS gate dielectric layer; and
forming an NMOS source diffused contact region in said p-type well adjacent to said NMOS gate;
forming an electrical connection between said DMOS gate and said NMOS gate; and
forming an electrical connection between said NMOS source diffused contact region and said NMOS body diffused contact region.

16. The method of claim 15, in which a channel width of said NMOS transistor is between one-third and two-thirds a channel width of said DMOS transistor.

17. The method of claim 16, in which said DMOS drain diffused contact region is separated from said DMOS gate dielectric layer by a region of field oxide.

18. The method of claim 16, in which said DMOS drain diffused contact region is separated from said DMOS gate dielectric layer by a region of insulating material formed on a top surface of said semiconductor substrate.
